(19) United States
(12) Patent Application Publication
(10) Pub. No.: US 2007/0024314 A1
(43) Pub. Date: Feb. 1, 2007

(54) Test system and single-chip tester capable of testing a plurality of chips simultaneously

(75) Inventors: Cheng-Yung Teng, Taipei County (TW); Yi-Chang Hsu, Taipei County (TW); Li-Jieu Hsu, Taipei City (TW)

Correspondence Address: BIRCH STEWART KOLASCH & BIRCH, PO BOX 747, FALLS CHURCH, VA, 22040-0747, US

(73) Assignee: Princeton Technology Corporation

(21) Appl. No.: 11/495,515

(22) Filed: Jul. 31, 2006

(30) Foreign Application Priority Data
Aug. 1, 2005 (TW) 094213065

(51) Int. Cl. G01R 31/26

(52) U.S. Cl. 324/765

(57) ABSTRACT

The present invention relates to a test system, and in particular relates to a test system capable of testing a plurality of chips simultaneously. The test system comprises a single-chip tester and a handler. The single-chip tester further comprises a pattern memory and a micro-processor. The pattern memory comprises a plurality of pattern units for respectively performing a function pattern test on the plurality of chips and generating a test result mapping to the plurality of chips. The micro-processor performs various tests and generating an interface control signal according to the test result. The handler initiates the micro-processor for performing various tests and receives the interface control signal to finish testing the plurality of chips. The pluralities of chips are set to the handler.

### BACKGROUND OF THE INVENTION

1. Field of the Invention

The present invention relates to a test system, and in particular to a test system capable of simultaneously testing a plurality of chips.

2. Description of the Related Art

A tester is utilized to test each chip before the chips are sold. If a chip passes the test, the chip can be sold. Otherwise, the chip must be discarded. There are various testers that can be divided into single chip testers and multi-chip testers by the number of testing chips. A single-chip tester is designed to test only one chip at one time while a multi-chip tester is designed to test a plurality of chips (e.g. 4 chips or 16 chips) at one time. For example, assume that the test duration of the single-chip tester is the same as that of the multi-chip tester. In the same period of time, the multi-chip tester can test four times more chips than the single-chip tester. In other words, if a single-chip tester and a multi-chip tester must test the same number of chips, the single-chip tester takes four times as long as the multi-chip tester. Hence, the performance of the multi-chip tester is better. A multi-chip tester, however, is more complicated and expensive. The user must consider performance and cost to determine which kind of tester is appropriate. A detailed description of utilizing the single chip tester to test chips is provided in the following.

Please refer to FIG. 1. FIG. 1 shows a schematic diagram of a related test system 100. The test system 100 comprises a single-chip tester 110, a test head 150, and a handler 170. The single-chip tester 110 comprises a plurality of device power supplies (DPS) 111˜114, a plurality of precision measurement units (PMU) 115˜118, a pattern memory 120, a counter 130, and a micro-processor 140. The test head 150 comprises a device under test (DUT) 151 and an interface control circuit 160. The handler 170 comprises a chip 171 and an interface board 180. A detailed description of each element is provided in the following.

The chip 171 is set to the handler 170 initially, connects to the DUT 151 through a bus, and sends a start signal to the single-chip tester 110 through the interface control circuit 160 for starting various tests. The common test comprises DC voltage test, DC current test, frequency test, and function pattern test. A detailed description of each test is provided in the following.

The DPSs 111, 112, 113, and 114 respectively provide four different DC voltage sources (e.g. 3, 5, 6, 12 volts) for DC voltage test of the chip 171. In practice, not every DC voltage source is utilized. Taking only one necessary DC voltage source as an example, the micro-processor 140 commands the DPS 111 to provide the voltage source for the chip 171. The DPS 111 then measures the voltage value between a ground terminal and a power supply voltage terminal of the chip 171. After finishing DC voltage test, a test result is generated and stored in registers (not shown) of the micro-processor 140. The PMUs 115, 116, 117, and 118 provide four different DC current sources for the DC current test of the chip 171. Similarly, not every DC current source is utilized. Taking only one necessary DC current source as an example, the micro-processor 140 commands the PMU 115 to provide the current source for the chip 171. The PMU 115 then measures the current value between a ground terminal and a power supply voltage terminal of the chip 171. After finishing the DC current test, the test result stored in registers of the micro-processor 140 is updated. The pattern memory 120 performs the function pattern test for the chip 171. After finishing the function pattern test, the test result stored in registers of the micro-processor 140 is updated. The counter 130 is utilized to perform the frequency test and the test result stored in registers of the micro-processor 140, is updated after finishing frequency test.

After the DC voltage test, the DC current test, the frequency test, and the function pattern test are complete, the micro-processor 140 generates an interface control signal according to the latest test result stored in the registers. After the interface control signal is sent to the handler 170 through the bus and driven by the interface board 180, the test for the chip 171 is complete.

The related single-chip tester has the advantage of low cost (compared with the related multi-chip tester), but, is excessively time-consuming particularly when testing a large number of chips.

### BRIEF SUMMARY OF THE INVENTION

A detailed description is given in the following embodiments with reference to the accompanying drawings.

The invention provides a test system capable of simultaneously testing a plurality of chips. The test system comprises a single-chip tester and a handler. The single-chip tester further comprises a pattern memory and a micro-processor. The pattern memory comprises a plurality of pattern units for respectively performing a function pattern test on the plurality of chips and generating a test result mapping to the plurality of chips. The micro-processor performs various tests and generates an interface control signal according to the test result. The handler initiates the micro-processor for performing various tests and receives the interface control signal to finish testing of the plurality of chips. The plurality of chips are set to the handler.

The invention further provides a single-chip tester capable of simultaneously testing a plurality of chips. The single-chip tester comprises a pattern memory and a micro-processor. The pattern memory comprises a plurality of pattern units for respectively performing a function pattern test on the plurality of chips and generating a test result mapping to the plurality of chips. The micro-processor performs various tests and generates an interface control signal to finish testing according to the test result. The interface control signal comprises a plurality of end of test signals, a pass signal, and a fail signal. The plurality of EOT signal represents complete statuses of different chips. The pass signal represents a pass status of a chip corresponding to an EOT signal. The fail signal represents a fail status of another chip corresponding to an EOT signal.

### BRIEF DESCRIPTION OF THE DRAWINGS

The present invention can be more fully understood by reading the subsequent detailed description and examples with references made to the accompanying drawings, wherein:

FIG. 1 shows a schematic diagram of a related test system;

FIG. 2 shows a schematic diagram of a test system according to an embodiment of the invention;

FIG. 3 shows a block diagram of the interface control circuit in FIG. 2;

FIG. 4 shows a block diagram of the interface board in FIG. 2;

FIG. 5 shows a timing diagram of the interface control signal.

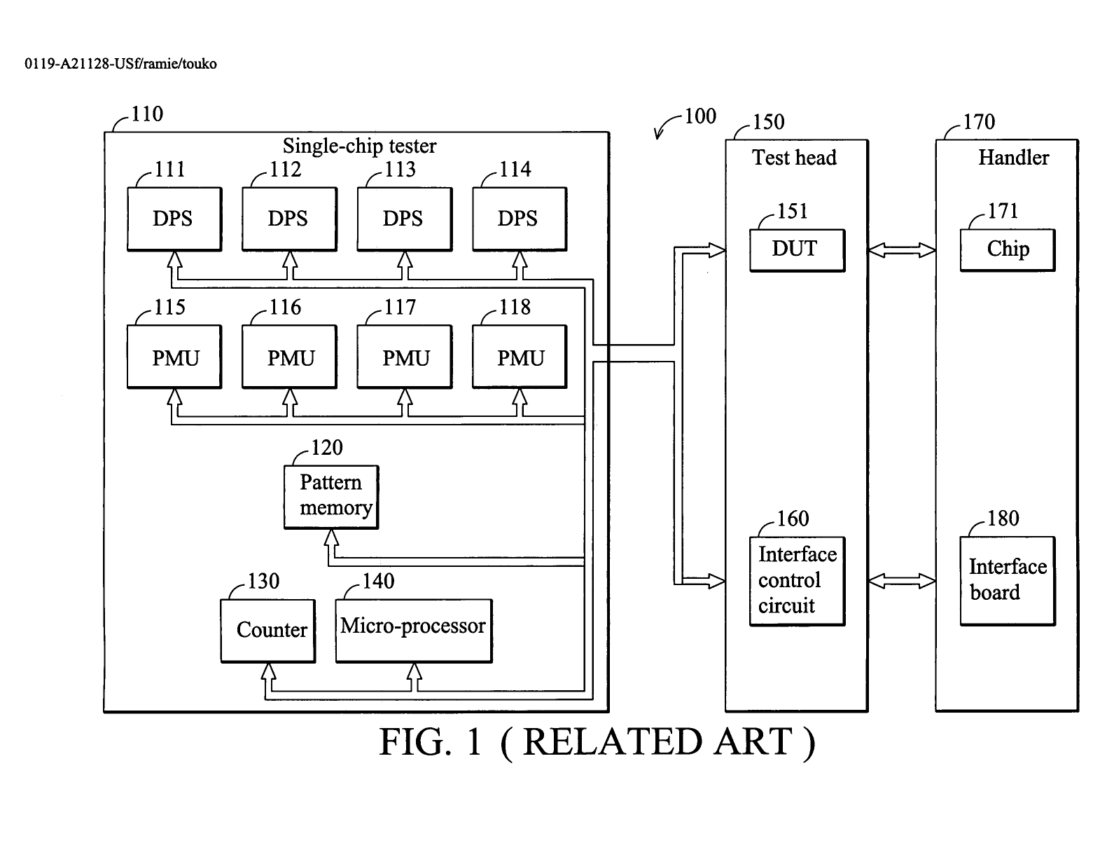

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

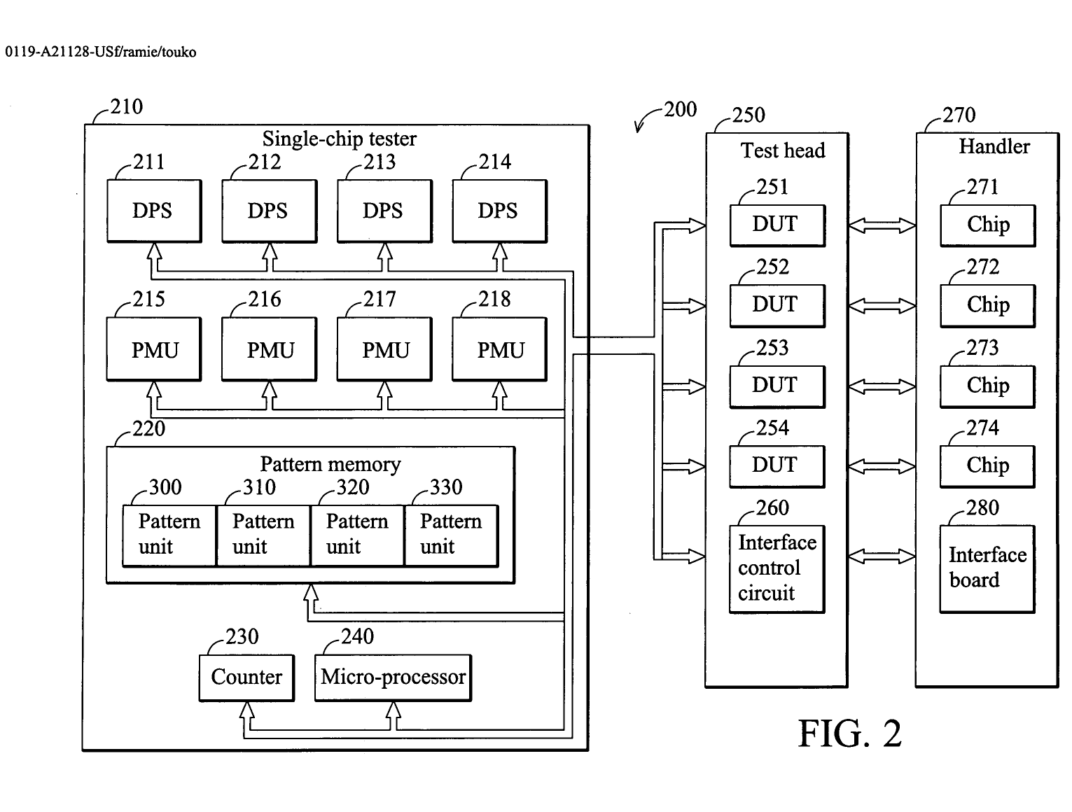

Please refer to FIG. 2. FIG. 2 shows a schematic diagram of a test system 200 according to an embodiment of the invention. The test system 200 utilizes the single-chip tester to test chips. The single-chip tester of the invention has the advantage of lower cost and can test a plurality of chips at one time. Compared with the related single-chip tester, the single-chip tester of the invention not only keeps the benefit of cost, but also consumes less test time. A detailed description is provided in the following.

The test system 200 comprises a single-chip tester 210, a test head 250, and a handler 270. The single-chip tester 210 comprises a plurality of device power supplies (DPS) 211˜214, a plurality of precision measurement units (PMU)215˜218, a pattern memory 220, a counter 230 and a micro-processor 240. The pattern memory 220 further comprises a plurality of pattern units 300,310,320, and 330. The test head 250 comprises a plurality of device under tests (DUT) 251˜254, and an interface control circuit 260. The handler 270 comprises a plurality of chips 271˜274, and an interface board 280. A detailed description of testing process is provided as follows. The plurality of chips 271˜274 are set to the handler 270 initially, connect to the plurality of DUTs 251˜254 through a bus, and send a start signal to the single-chip tester 210 through the interface control circuit 260 for starting various tests. A detailed description of DC voltage test, DC current test, frequency test, and function pattern test is provided in the following.

The DPSs 211˜214 respectively provide voltage sources (usually the same) for the chips 271˜274 to simultaneously perform DC voltage test to the chips 271˜274. The micro-processor 240 controls these DPSs to measure each voltage value between a ground terminal and a power supply voltage terminal of the chips 271˜274, and to determine whether the DC voltage test of each chip is passed. After finishing the DC voltage test, a test result is generated and stored in registers (not shown) of the micro-processor 240. The PMUs 215˜218 respectively provide current sources (usually the same) for the chips 271˜274 to simultaneously perform a DC current test on the chips 271˜274. The micro-processor 240 controls these PMUs to measure each current value between a ground terminal and a power supply voltage terminal of the chips 271˜274, and to determine whether the DC current test of each chip is passed. After finishing DC current test, the test result in registers (not shown) of the micro-processor 240 is updated.

The pattern units 300˜330 respectively perform a function pattern test on the chips 271˜274 simultaneously. The micro-processor 240 controls the function pattern test and updates the test result when finished. Compared with the related single-chip tester 110, the single-chip tester 210 of the invention divides the pattern memory 220 into pluralities of pattern units 300˜330 to perform the function pattern test on different chips at the same time. Additionally, since the pattern memory 220 is divided, the pattern vector decreases. Assume that the pin number of the single-chip testers 110 and 210 are both equal to an integer M. The pattern vector of a chip in the single-chip tester 110 (chip 171) is then also equal to M while the pattern vector of a chip in the single-chip testers 210 (chip 271, 272, 273, or 274) is equal to M divided by N (N is equal to the number of the chips and is also the number of the pattern units). In other words, the number of available pins of the single-chip tester 110 is N times larger than the number of available pins of the single-chip tester 210.

Typically, there is only one counter (counter 230) in the single-chip tester 210. The counter 230 switches to different chips at different times to perform a frequency test on the chips 271˜274. The greater the number of chips, the more time the frequency test requires.

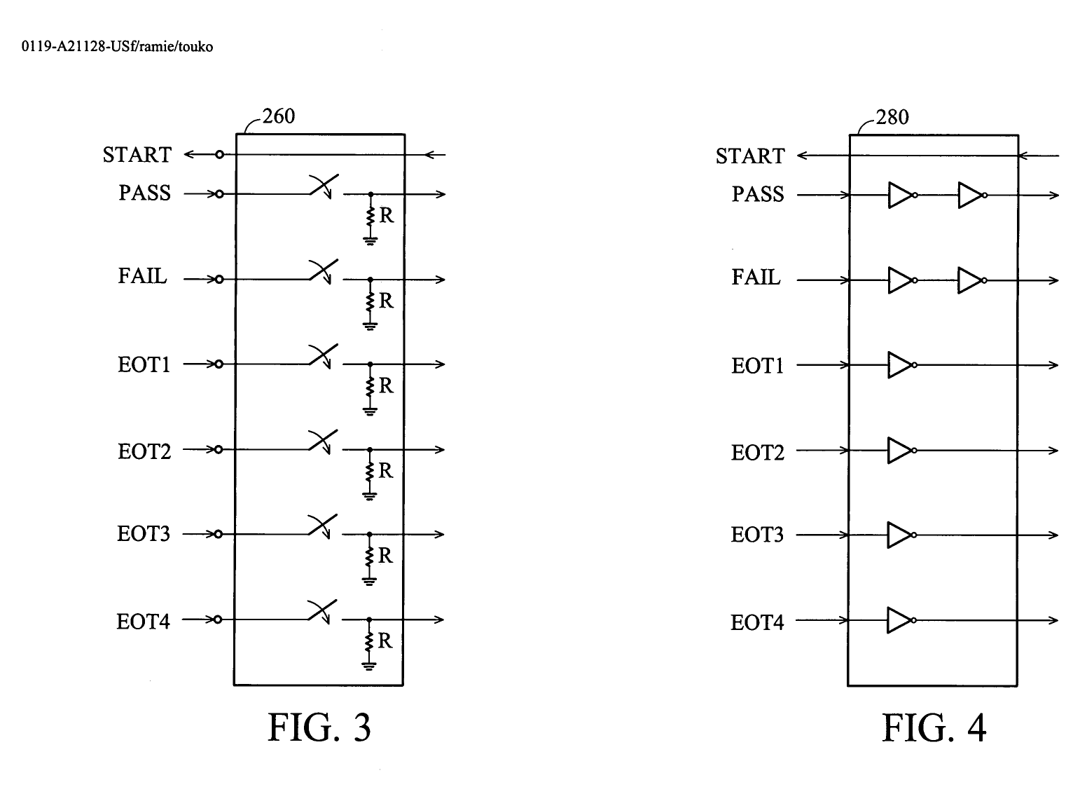

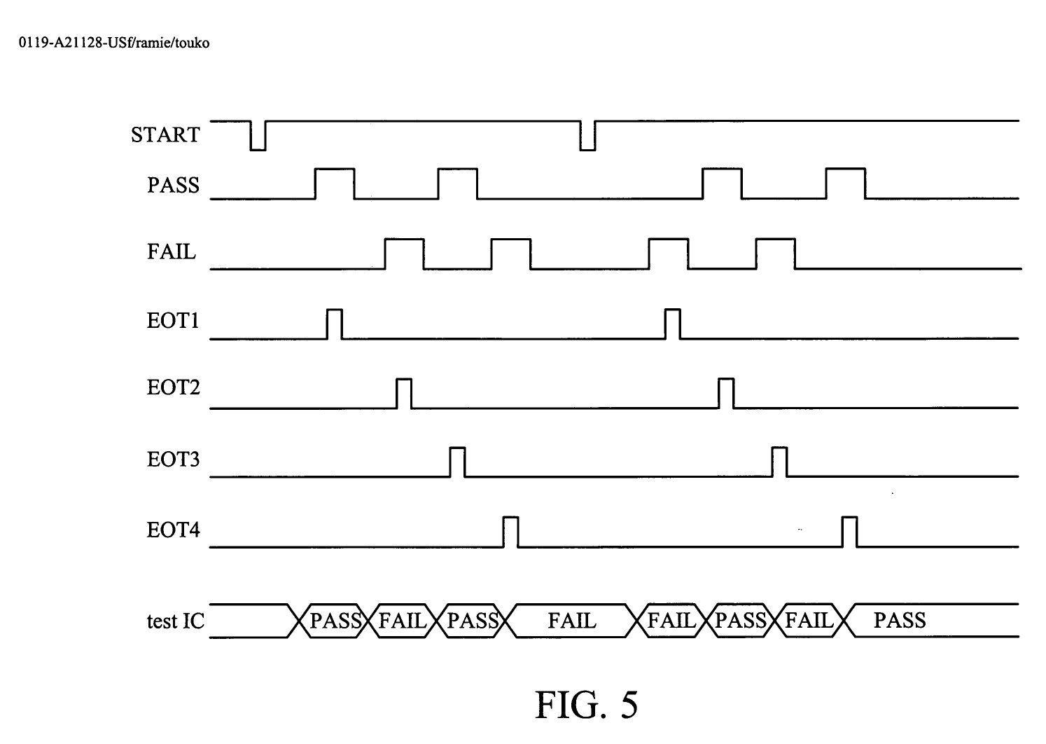

Please refer to FIG. 3, FIG. 4, and FIG. 5 at the same time. FIG. 3 shows a block diagram of the interface control circuit 260, FIG. 4 shows a block diagram of the interface board 280, and FIG. 5 shows a timing diagram of the interface control signal. After the DC voltage test, the DC current test, the frequency test, and the function pattern test are finished, the micro-processor 240 generates an interface control signal (as shown in FIG. 5) according to the latest test result stored in the registers. After the interface control signal is sent to the handler 270 through the bus and driven by the interface board 280, the test for the chips 271˜274 is complete. Please refer to FIG. 3 and FIG. 4 at the same time. In an embodiment, the interface control circuit 260 and interface board 280 respectively utilize its relay and OP amplifier to send and drive the interface control signal. A detailed description is omitted for the sake of brevity since it is familiar to those skilled in the art. Please refer to FIG. 5. The interface control signal comprises a plurality of end of test (EOT) signals EOT1, EOT2, EOT3, and EOT4, a pass signal PASS, and a fail signal FAIL. The EOT signals EOT1, EOT2, EOT3, and EOT4 respectively represent complete statuses of chips 271,272,273, and 274. The pass signal represents a pass status of a chip corresponding to an EOT signal. The fail signal represents a fail status of another chip corresponding to an EOT signal. As shown in FIG. 5, taking the first test started by start signal START as an example, the EOT signal EOT1 shows that the chip 271 is in a pass status, the EOT signal EOT2 shows that the chip 272 is in a fail status, the EOT signal EOT3 shows that the chip 273 is in a pass status, and the EOT signal EOT4 shows that the chip 274 is in a fail status.

Compared with the related art, the test system utilizes a modified single-chip tester to test a plurality of chips at one time to save the test time and keeps the benefit of cost.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A test system capable of testing a plurality of chips simultaneously, the test system comprising:
a single-chip tester comprising:
a pattern memory comprising:
a plurality of pattern units for respectively performing a function pattern test on the plurality of chips and generating a test result mapping to the plurality of chips; and
a micro-processor for performing various tests and generating an interface control signal according to the test result; and
a handler coupled to the single-chip tester for initiating the micro-processor for performing various tests and receiving the interface control signal to finish testing the plurality of chips wherein the plurality of chips are set to the handler;
wherein the interface control signal comprises a plurality of the end of test signals (EOT signals), a pass signal, and a fail signal; the plurality of EOT signals represent complete statuses of different chips; the pass signal represents a pass status of a chip corresponding to an EOT signal; and the fail signal represents a fail status of another chip corresponding to an EOT signal.

2. The test system as claimed in claim 1, wherein each pattern vector of the pattern unit corresponding to each chip is equal to M divided by N, wherein M is the pin number of the tester and N is the number of the plurality of chips.

3. The test system as claimed in claim 1, wherein the handler sends a start signal for starting the single-chip tester to perform various tests.

4. The test system as claimed in claim 1, wherein the tester further comprises:
a plurality of device power supplies (DPS) for simultaneously providing voltage sources for the plurality of chips, measuring each voltage value between a ground terminal and a power supply voltage terminal of the plurality of chips to perform DC voltage test to the plurality of chips simultaneously; and
a plurality of Precision Measurement Units (PMU) for simultaneously providing current sources for the plurality of chips, measuring each current value between a ground terminal and a power supply voltage terminal of the plurality of chips to perform DC current test to the plurality of chips simultaneously;
wherein the micro-processor commands the tester to generate the test results of the plurality of chips after finishing the function pattern test, voltage test, and current test.

5. The test system as claimed in claim 4, wherein the tester further comprises:
a counter for switching to different chips at different times to perform a frequency test on the plurality of chips;
wherein the micro-processor commands the tester to generate the test results of the plurality of chips after finishing the function pattern test, voltage test, current test, and frequency test.

6. The test system as claimed in claim 5, wherein the tester further comprises at least one register for storing the test result.

7. A single-chip tester capable of testing a plurality of chips simultaneously, the single-chip tester comprising:
a pattern memory comprising:
a plurality of pattern units for respectively performing function pattern test to the plurality of chips and generating a test result mapping to the plurality of chips; and
a micro-processor for performing various tests and generating an interface control signal to finish testing according to the test result;
wherein the interface control signal comprises a plurality of end of test signals (EOT signals), a pass signal, and a fail signal; the plurality of EOT signal represents complete statuses of different chips; the pass signal represents a pass status of a chip corresponding to an EOT signal; and the fail signal represents a fail status of another chip corresponding to an EOT signal.

8. The single-chip tester as claimed in claim 7, wherein each pattern vector of the pattern unit corresponding to each chip is equal to M divided by N, wherein M is the pin number of the tester and N is the number of the plurality of chips.

9. The single-chip tester as claimed in claim 7, wherein the single-chip tester further comprises:
a plurality of device power supplies (DPS) for simultaneously providing voltage sources for the plurality of chips, measuring each voltage value between a ground terminal and a power supply voltage terminal of the plurality of chips, to perform DC voltage test to the plurality of chips simultaneously; and
a plurality of Precision Measurement Units (PMU) for simultaneously providing current sources for the plurality of chips, measuring each current value between a ground terminal and a power supply voltage terminal of the plurality of chips to perform DC current test to the plurality of chips simultaneously;
wherein the micro-processor commands the single-chip tester to generate the test results of the plurality of chips after finishing the function pattern test, voltage test, and current test.

10. The single-chip tester as claimed in claim 9, wherein the single-chip tester further comprises:
a counter for switching to different chips at different times for performing a frequency test on the plurality of chips;
wherein the micro-processor commands the tester to generate the test results of the plurality of chips after finishing the function pattern test, voltage test, current test, and frequency test.

11. The single-chip tester as claimed in claim 10, wherein the single-chip tester further comprises at least one register for storing the test result.
